(19) United States
(12) Patent Application Publication
(10) Pub. No.: US 2026/0280222 A1
(43) Pub. Date: Sep. 17, 2026

(54) COMPOSITE SUBSTRATE AND METHOD OF PRODUCING COMPOSITE SUBSTRATE

(71) Applicant: NGK Corporation, Nagoya-shi (JP)

(72) Inventors: Jungo KONDO, Miyoshi-shi (JP); Kentaro TANI, Nagoya-shi (JP); Tetsuya EJIRI, Kasugai-shi (JP)

(21) Appl. No.: 19/670,485

(22) Filed: May 7, 2026

Related U.S. Application Data
(63) Continuation of application No. PCT/JP2024/040058, filed on Nov. 12, 2024.

(30) Foreign Application Priority Data
Nov. 14, 2023 (JP) 2023-193965
Jun. 24, 2024 (JP) 2024-101481

(51) Int. Cl. H01S 5/02; H01S 5/065; H01S 5/183

(52) U.S. Cl. CPC H01S 5/0206; H01S 5/0657; H01S 5/183

(57) ABSTRACT

A composite substrate includes: a wavelength conversion layer configured to convert incident light into light having a different wavelength; and a multilayer film arranged adjacent to the wavelength conversion layer, wherein the multilayer film is a laminate of a plurality of refractive index layers, and wherein, in one of the plurality of refractive index layers included in the multilayer film, an amorphous region in which an inert gas atom is present is formed in a central portion in a thickness direction.

### CROSS-REFERENCE TO RELATED APPLICATIONS

This application is a continuation under 35 U.S.C. 120 of International Application PCT/JP2024/040058 having the International Filing Date of Nov. 12, 2024 and having the benefit of the earlier filing dates of Japanese Application No. 2023-193965, filed on Nov. 14, 2023 and Japanese Application No. 2024-101481, filed on Jun. 24, 2024. Each of the identified applications is fully incorporated herein by reference.

### BACKGROUND OF THE INVENTION

### 1. Field of the Invention

The present disclosure relates to a composite substrate and a method of producing a composite substrate.

### 2. Description of the Related Art

Solid-state lasers capable of outputting short-pulse light are widely used. A laser having extremely high optical output at an even shorter pulse width is expected to be applied in sensing, precision processing, medicine, and various other fields. As a laser of this kind, as disclosed in, for example, Patent Literature 1, a laser configuration that is a combination of a semiconductor laser, a solid-state laser gain medium layer capable of functioning as a wavelength conversion layer, and a saturable absorber has been proposed.

### CITATION LIST

### Patent Literature

[PTL 1] WO 2020/166420 A1

### SUMMARY OF THE INVENTION

In the laser configuration described above, a light reflection characteristic at an interface of the wavelength conversion layer may significantly affect the performance of the laser.

The present disclosure has been made in view of the foregoing, and has a primary object to provide a composite substrate excellent in reflection characteristic at an interface of a wavelength conversion layer.
1. According to an embodiment of the present disclosure, there is provided a composite substrate including: a wavelength conversion layer configured to convert incident light into light having a different wavelength; and a multilayer film arranged adjacent to the wavelength conversion layer, wherein the multilayer film is a laminate of a plurality of refractive index layers, and wherein, in one of the plurality of refractive index layers included in the multilayer film, an amorphous region in which an inert gas atom is present is formed in a central portion in a thickness direction.
2. In the composite substrate according to the above-mentioned item 1, an abundance of the inert gas atom in the amorphous region may be 0.5 at % or more and 10 at % or less.
3. In the composite substrate according to the above-mentioned item 1 or 2, the wavelength conversion layer may be selected from a doped yttrium aluminum garnet crystal, a doped yttrium vanadate crystal, and a doped yttrium lithium fluoride crystal.
4. In the composite substrate according to any one of the above-mentioned items 1 to 3, the one of the plurality of refractive index layers in which the amorphous region in which the inert gas atom is present is formed may include an oxide containing at least one selected from tantalum, titanium, aluminum, yttrium, zirconium, hafnium, lanthanum, cerium, tungsten, zinc, niobium, and magnesium.
5. In the composite substrate according to any one of the above-mentioned items 1 to 4, two neighboring layers included in the multilayer film may have refractive indices different from each other.
6. In the composite substrate according to any one of the above-mentioned items 1 to 5, the plurality of refractive index layers included in the multilayer film may each have a refractive index of from 1.3 to 2.4, and the multilayer film may include one or more refractive index layers each having a refractive index of 2.1 or more.
7. In the multilayer film of the composite substrate according to any one of the above-mentioned items 1 to 6, a difference between a highest refractive index and a lowest refractive index among refractive indices of the plurality of refractive index layers may be 0.5 or more.
8. In the composite substrate according to any one of the above-mentioned items 1 to 7, the plurality of refractive index layers included in the multilayer film each have a thickness of 50 nm or more and 300 nm or less.
9. The composite substrate according to any one of the above-mentioned items 1 to 8 may include the wavelength conversion layer, the multilayer film, and a surface emitting laser substrate in the stated order.
10. The composite substrate according to any one of the above-mentioned items 1 to 9 may include the wavelength conversion layer, the multilayer film, and a saturable absorber layer in the stated order.
11. According to another embodiment of the present disclosure, there is provided a composite substrate including in the following order: a surface emitting laser substrate; a wavelength conversion layer configured to convert incident light into light having a different wavelength; and a saturable absorber layer, wherein the composite substrate further includes a multilayer film arranged adjacent to the wavelength conversion layer, in at least one of a space between the surface emitting laser substrate and the wavelength conversion layer or a space between the saturable absorber layer and the wavelength conversion layer, wherein the multilayer film is a laminate of a plurality of refractive index layers, and wherein, in one of the plurality of refractive index layers included in the multilayer film, an amorphous region in which an inert gas atom is present is formed in a central portion in a thickness direction.
12. According to an embodiment of the present disclosure, there is provided a laser structure including the composite substrate of any one of the above-mentioned items 1 to 11.
13. According to an embodiment of the present disclosure, there is provided a method of producing the composite substrate of any one of the above-mentioned items 1 to 8, the method including: preparing a first part for forming the laminate of the plurality of refractive index layers; laminating a second part for forming the laminate of the plurality of refractive index layers onto the wavelength conversion layer; subjecting each of a surface of the first part and a surface of the second part to activation treatment; and joining the first part and the second part to each other after the activation treatment, wherein a material for forming an outermost layer of the first part and a material for forming an outermost layer of the second part are substantially the same as each other.
14. In the method of producing the composite substrate according to the above-mentioned item 13, a length of time of the activation treatment may be from 10 seconds to 30 seconds for each of the surface of the first part and the surface of the second part.

According to the embodiment of the present disclosure, it is possible to provide the composite substrate excellent in reflection characteristic at the interface of the wavelength conversion layer.

### BRIEF DESCRIPTION OF THE DRAWINGS

FIG. 1 is a schematic sectional view for illustrating a schematic configuration of a composite substrate according to one embodiment of the present disclosure.

FIG. 2 is a partially enlarged sectional view of a first refractive index layer.

FIG. 3A is a view for illustrating an example of a production process for a composite substrate according to one embodiment.

FIG. 3B is a view subsequent to FIG. 3A.

FIG. 3C is a view subsequent to FIG. 3B.

FIG. 3D is a view subsequent to FIG. 3C.

FIG. 4 is a graph for showing a simulation result of a reflection characteristic of a multilayer film in Example 1.

FIG. 5 is a graph for showing a simulation result of a reflection characteristic of a multilayer film in Comparative Example 1.

FIG. 6 is a graph for showing a simulation result of a reflection characteristic of a multilayer film in Example 2.

FIG. 7 is a graph for showing a simulation result of a reflection characteristic of a multilayer film in Example 3.

FIG. 8 is a graph for showing a simulation result of a reflection characteristic of a multilayer film in Example 4.

### DESCRIPTION OF THE EMBODIMENTS

Embodiments of the present disclosure are described below with reference to the drawings. However, the present disclosure is not limited to those embodiments. In order to further clarify the description, the width, thickness, shape, and the like of each portion may be schematically illustrated in the drawings as compared to the embodiments, but the illustration is merely an example and does not limit the interpretation of the present disclosure. In addition, in the drawings, the same or similar components are denoted by the same reference symbols, and repetitive description thereof may be omitted.

### [Composite Substrate]

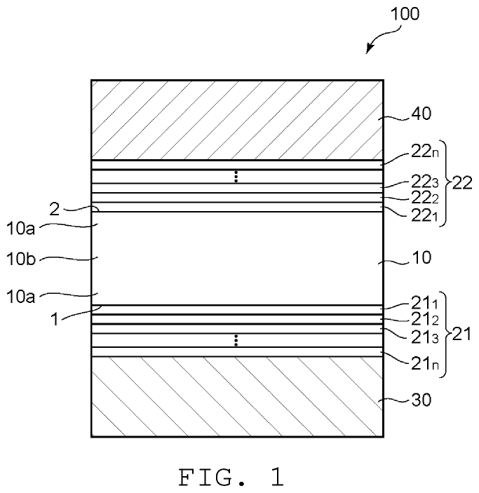

FIG. 1 is a schematic sectional view for illustrating a schematic configuration of a composite substrate according to one embodiment of the present disclosure. For easy viewing, hatching of some members is omitted in FIG. 1.

A composite substrate 100 includes: a wavelength conversion layer 10 which has a first main surface 1 and a second main surface 2 facing each other and which converts incident light into light having a different wavelength; a first multilayer film 21 arranged adjacent to the first main surface 1 of the wavelength conversion layer 10; a second multilayer film 22 arranged adjacent to the second main surface 2 of the wavelength conversion layer 10; a substrate 30 arranged on the first multilayer film 21 side of the wavelength conversion layer 10; and a function layer 40 arranged on the second multilayer film 22 side of the wavelength conversion layer 10.

The composite substrate 100 is applicable to, for example, a laser device. The substrate 30 is a substrate for forming, for example, a surface emitting laser (e.g., a vertical cavity surface emitting laser (VCSEL) or a vertical external cavity surface emitting laser (VECSEL)). The wavelength conversion layer 10 is capable of converting, for example, a first wavelength of laser light that enters from the first main surface 1 side thereof into a second wavelength. Although not shown, a cavity structure portion may be arranged in the substrate 30.

As the substrate for forming a surface emitting laser, for example, a gallium arsenide substrate, an indium phosphide substrate, or a gallium nitride substrate is used. The substrate for forming a surface emitting laser has a thickness of, for example, from 100 μm to 1,000 μm.

The wavelength conversion layer 10 is formed of any appropriate wavelength conversion material capable of converting incident light into light having a different wavelength. As a material for forming the wavelength conversion layer 10, a doped yttrium aluminum garnet (hereinafter referred to as “YAG”) crystal is typically used. Specific examples of the doped YAG crystal include an YAG crystal doped with Yb³⁺ (Yb:YAG) and an YAG crystal doped with Nd³⁺ (Nd:YAG). As another material for forming the wavelength conversion layer 10, for example, a doped yttrium vanadate (hereinafter referred to as “YVO₄”) crystal or a doped yttrium lithium fluoride (hereinafter referred to as “YLF”) crystal is used. Specific examples of the doped YVO₄ crystal include an YVO₄ crystal doped with Yb³⁺ (Yb:YVO₄) and an YVO₄ crystal doped with Nd³⁺ (Nd:YVO₄). Specific examples of the doped YLF crystal include an YLF crystal doped with Yb³⁺ (Yb:YLF) and an YLF crystal doped with Nd³⁺ (Nd:YLF). In addition, examples of another material for forming the wavelength conversion layer 10 include Nd:glass, Yb:FAP, Yb:SFAP, Yb:glass, Yb:KYW, Yb:BCBF, Yb:YCOB, Yb:GdCOB, and Yb:YAB. Of those, a doped YAG crystal, a doped YVO₄ crystal, and a doped YLF crystal are preferred as another material for forming the wavelength conversion layer 10. Those materials are each capable of exhibiting similar adhesion to, for example, an adjacent layer. The wavelength conversion layer 10 has a thickness of, for example, from 10 μm to 600 μm.

The first multilayer film 21 is a laminate of a plurality of refractive index layers. In the illustrated example, the first multilayer film 21 includes “n” layers from a first refractive index layer 21₁, a second refractive index layer 21₂, a third refractive index layer 21₃, . . . , and an n-th refractive index layer 21ₙ from the wavelength conversion layer 10 side. Specifically, the refractive index layer positioned closest to the wavelength conversion layer 10 is the first refractive index layer 21₁, and the refractive index layer positioned closest to the substrate 30 is the n-th refractive index layer 21ₙ. A number represented by “n” is, for example, from 10 to 50, preferably from 15 to 40. Each of the layers included in the first multilayer film 21 has a thickness of, for example, 50 nm or more and 300 nm or less.

The first multilayer film 21 includes a plurality of refractive index layers having different refractive indices, and includes high refractive index layers each having a relatively high refractive index and low refractive index layers each having a relatively low refractive index. For example, two neighboring layers included in the first multilayer film 21 have refractive indices different from each other, with one of the two being a high refractive index layer and the other being a low refractive index layer. In addition, for example, at least a part of the first multilayer film 21 may be formed by alternately laminating a high refractive index layer and a low refractive index layer. As a specific example, the second refractive index layer 21₂ may have a lower or higher refractive index than those of the first refractive index layer 21₁ and the third refractive index layer 21₃. In this case, the refractive index of the first refractive index layer 21₁ and the refractive index of the third refractive index layer 21₃ may be substantially the same as each other or may differ from each other.

The first multilayer film 21 is formed so as to be capable of transmitting light having the first wavelength that has been emitted from the substrate 30 side. Specifically, the first multilayer film 21 is formed so as to be capable of functioning as a transmissive layer or an antireflection layer with respect to light having the first wavelength. From the viewpoint of, for example, improving light utilization efficiency, the first multilayer film 21 is also formed so as to be capable of suppressing emission of light having the second wavelength from the wavelength conversion layer 10 to the substrate 30 side. Specifically, the first multilayer film 21 is formed so as to be capable of functioning as a reflective layer with respect to light having the second wavelength. Those functions of the first multilayer film 21 may be achieved by, for example, adjusting the number (“n” described above) of refractive index layers for forming the first multilayer film 21, the thicknesses of the respective refractive index layers, and the refractive indices of the respective refractive index layers.

Laser light that has entered from the first main surface 1 (substrate 30) side may be emitted from the second main surface 2 side. For example, light having the second wavelength having been converted by the wavelength conversion layer 10 may be transmitted through the function layer 40 to be emitted. The function layer 40 is capable of functioning as, for example, a saturable absorber layer. In this case, the function layer (saturable absorber layer) 40 may be formed typically of a material, such as an YAG crystal doped with Cr⁴⁺ (Cr:YAG) or an YAG crystal doped with V³⁺ (V:YAG). The function layer (saturable absorber layer) 40 has a thickness of, for example, from 10 μm to 600 μm.

The second multilayer film 22 is a laminate of a plurality of refractive index layers. In the illustrated example, the second multilayer film 22 includes “n” layers from a first refractive index layer 22₁, a second refractive index layer 22₂, a third refractive index layer 22₃, and an n-th refractive index layer 22ₙ from the wavelength conversion layer 10 side. Specifically, the layer positioned closest to the wavelength conversion layer 10 is the first refractive index layer 22₁, and the layer positioned closest to the function layer 40 is the n-th refractive index layer 22ₙ. A number represented by “n” is, for example, from 10 to 50, preferably from 15 to 40. Each of the refractive index layers included in the second multilayer film 22 has a thickness of, for example, 50 nm or more and 300 nm or less.

The second multilayer film 22 includes a plurality of refractive index layers having different refractive indices, and includes high refractive index layers each having a relatively high refractive index and low refractive index layers each having a relatively low refractive index. For example, two neighboring layers included in the second multilayer film 22 have refractive indices different from each other, with one of the two being a high refractive index layer and the other being a low refractive index layer. In addition, for example, at least a part of the second multilayer film 22 may be formed by alternately laminating a high refractive index layer and a low refractive index layer. As a specific example, the second layer 22₂ may have a lower or higher refractive index than those of the first refractive index layer 22₁ and the third refractive index layer 22₃. In this case, the refractive index of the first refractive index layer 22₁ and the refractive index of the third refractive index layer 22₃ may be substantially the same as each other or may differ from each other.

The second multilayer film 22 is formed so as to be capable of transmitting light that has been emitted from the wavelength conversion layer 10 and that has the second wavelength. Specifically, the second multilayer film 22 is formed so as to be capable of functioning as a transmissive layer or an antireflection layer with respect to light having the second wavelength. From the viewpoint of, for example, improving light utilization efficiency, the second multilayer film 22 is also formed so as to be capable of suppressing emission of light having the first wavelength from the wavelength conversion layer 10 to the function layer 40 side. Specifically, the second multilayer film 22 is formed so as to be capable of functioning as a reflective layer with respect to light having the first wavelength. Those functions of the second multilayer film 22 may be achieved by, for example, adjusting the number (“n” described above) of refractive index layers for forming the second multilayer film 22, the thicknesses of the respective refractive index layers, and the refractive indices of the respective refractive index layers.

As described above, the first multilayer film 21 and the second multilayer film 22 (hereinafter sometimes simply referred to as “multilayer films”) are each a laminate of a plurality of refractive index layers, and may include a high refractive index layer and a low refractive index layer which have refractive indices different from each other. The refractive index of each of the refractive index layers included in each of the multilayer films (the refractive index of a material for forming each of the refractive index layers included in each of the multilayer films) is, for example, from 1.3 to 2.4, preferably from 1.4 to 2.4, more preferably from 1.45 to 2.35. The refractive index may be a value measurable with a spectroscopic ellipsometer or a spectral photometer. The refractive index of the high refractive index layer is relatively higher than the refractive index of the low refractive index layer. Specifically, the refractive index of a material for forming the high refractive index layer is higher than the refractive index of a material for forming the low refractive index layer. The refractive index of the low refractive index layer is, for example, from 1.3 to 1.8. The refractive index of the high refractive index layer is, for example, from 1.55 to 2.4.

A plurality of low refractive index layers that may be included in each of the multilayer films may have the same configuration (e.g., in terms of material and thickness) as one another, or configurations different from one another. In the same manner, a plurality of high refractive index layers that may be included in each of the multilayer films may have the same configuration (e.g., in terms of material and thickness) as one another, or configurations different from one another.

Each of the multilayer films preferably includes one or more refractive index layers each having a refractive index of 2.1 or higher. When each of the multilayer films include such refractive index layers, a desired transmission characteristic (reflection characteristic) can be satisfactorily achieved. In each of the multilayer films, a difference between a highest refractive index and a lowest refractive index among the refractive indices of the refractive index layers is preferably 0.5 or more, more preferably 0.6 or more, still more preferably 0.7 or more. From the viewpoint of satisfying the condition about the difference, each of the multilayer films preferably includes one or more refractive index layers each having a refractive index of 1.5 or less.

As a material for forming each of the refractive index layers included in each of the multilayer films, a dielectric material is typically used. Specific examples of the material for forming each of the refractive index layers included in each of the multilayer films include silicon oxide, tantalum oxide, titanium oxide, aluminum oxide, yttrium oxide, zirconium oxide, hafnium oxide, lanthanum oxide, cerium oxide, tungsten oxide, zinc oxide, niobium oxide, and magnesium oxide. Those materials may be used alone or in combination thereof (e.g., as a composite oxide). Specifically, the refractive index layer may be formed of an oxide containing at least one selected from silicon, tantalum, titanium, aluminum, yttrium, zirconium, hafnium, lanthanum, cerium, tungsten, zinc, niobium, and magnesium.

Each refractive index layer included in the multilayer film may be formed by any appropriate method. Each refractive index layer included in the multilayer film may be formed by, for example, physical deposition, such as sputtering or ion beam assisted deposition (IAD), chemical deposition, or an atomic layer deposition (ALD) method.

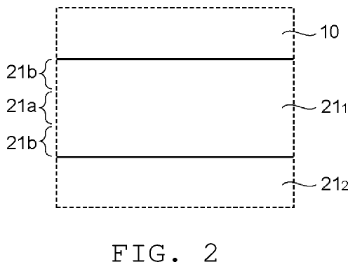

An inert gas atom is present in one refractive index layer (e.g., the first refractive index layer) included in each of the multilayer films. Examples of the typical inert gas atom include argon and xenon. For example, in one refractive index layer (e.g., the first refractive index layer) included in each of the multilayer films, an amorphous region in which the inert gas atom is present is formed. FIG. 2 is a partially enlarged sectional view of the first refractive index layer. The amorphous region in which the inert gas atom is present may be formed in a central portion 21a of the first refractive index layer 21₁ in a thickness direction. The amorphous region in which the inert gas atom is present may be formed so as to extend over the entire thickness of the first refractive index layer 21₁. For example, in the first refractive index layer 21₁, an amorphous layer in which the inert gas atom is present may be formed in the central portion 21a in the thickness direction. In the region (layer) in which the inert gas atom is present, an abundance of the inert gas atom is, for example, 0.5 at % or more and 10 at % or less, preferably 0.7 at % or more and 5 at % or less. A thickness of the region (layer) in which the inert gas atom is present is, for example, 0.5 nm or more, and may be 1 nm or more. Meanwhile, the thickness of the region (layer) in which the inert gas atom is present is, for example, 100 nm or less, preferably 50 nm or less. An element incorporated into an end portion 21b of the first refractive index layer 21₁ in the thickness direction may also be incorporated into the central portion 21a in the thickness direction in which the amorphous region (layer) in which the inert gas atom is present is formed.

An inert gas atom is preferably substantially absent in any other layer (e.g., layers other than the first refractive index layer) included in the multilayer film. An abundance of an inert gas atom in the other layer included in the multilayer film is, for example, less than 0.5 at %, and may be 0.4 at % or less. Although the state of the presence of an inert gas atom has been described by taking the first refractive index layer as an example for convenience in the example illustrated in FIG. 2, an inert gas atom may be selectively present in any other layer included in the multilayer film.

An inert gas atom is preferably substantially absent in the wavelength conversion layer 10. An abundance of an inert gas atom in the wavelength conversion layer 10 is, for example, less than 0.5 at %, and may be 0.4 at % or less.

The above-mentioned abundances of an inert gas atom can be obtained by composition analysis by, for example, energy dispersive X-ray spectroscopy (EDX).

Specific examples of a material for forming the refractive index layer in which the inert gas atom is present include tantalum oxide, titanium oxide, aluminum oxide, yttrium oxide, zirconium oxide, hafnium oxide, lanthanum oxide, cerium oxide, tungsten oxide, zinc oxide, niobium oxide, or magnesium oxide. Those materials may be used alone or in combination thereof (e.g., as a composite oxide). Specifically, the refractive index layer in which the inert gas atom is present may be formed of an oxide containing at least one selected from tantalum, titanium, aluminum, yttrium, zirconium, hafnium, lanthanum, cerium, tungsten, zinc, niobium, and magnesium. According to such configuration, adhesion (e.g., adhesion at a joining interface) can be excellent. When the refractive index layer is formed of an oxide containing at least one of tantalum or titanium out of those materials, more excellent adhesion can be achieved.

From the composite substrate 100, the function layer 40 and the second multilayer film 22 may be omitted, or the substrate 30 and the first multilayer film 21 may be omitted. In addition, although not shown, the composite substrate 100 may further include any appropriate layer. The kinds, functions, number, combination, arrangement, and the like of such layers may be appropriately set in accordance with purposes. For example, the composite substrate 100 may include another function layer (e.g., light scanner layer) arranged on the function layer 40.

The composite substrate 100 may be produced in any appropriate shape. In one embodiment, the composite substrate 100 may be produced in the form of a so-called wafer. The size of the composite substrate 100 may be appropriately set in accordance with purposes. For example, the diameter of the wafer is from 50 mm to 150 mm. In addition, for example, the diameter of the wafer is from 3 inches to 6 inches.

### [Production Method]

The above-mentioned composite substrate can be obtained by, for example, preparing a first part for forming a laminate of a plurality of refractive index layers, laminating a second part for forming the laminate of a plurality of refractive index layers onto a wavelength conversion layer, and joining the first part and the second part to each other.

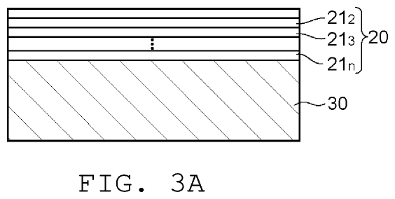

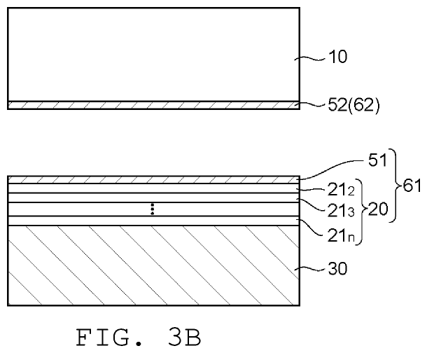

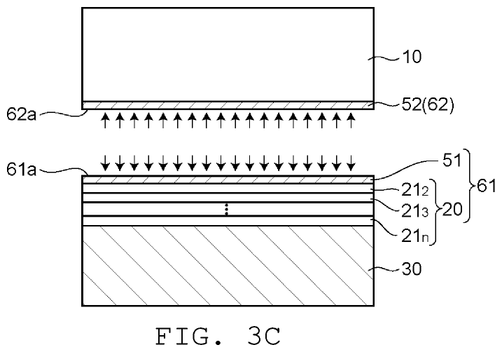

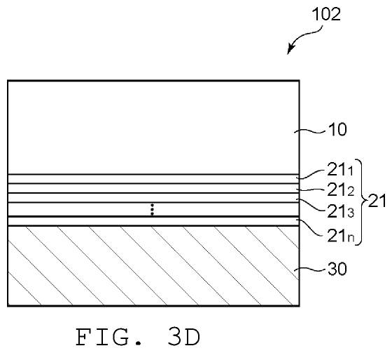

FIG. 3A to FIG. 3D are each a view for illustrating an example of a production process for a composite substrate according to one embodiment. FIG. 3A is an illustration of a state in which “n” layers from the second refractive index layer 21₂ to the n-th refractive index layer 21ₙ which may form the first multilayer film 21 are formed on the substrate 30 in the stated order from the n-th refractive index layer 21ₙ to form a laminated structure 20 of n−1 layers on the substrate 30.

Next, as illustrated in FIG. 3B, a first outermost layer 51 formed of a material for forming the first refractive index layer 21₁ is formed on a surface of the laminated structure 20 to form a first part 61 including the laminated structure 20 and the first outermost layer 51. Then, a second outermost layer 52 (second part 62) formed of the material for forming the first refractive index layer 21₁ is formed on the wavelength conversion layer (wavelength conversion material substrate) 10 which has been separately prepared.

A material for forming the first outermost layer 51 and a material for forming the second outermost layer 52 are substantially the same as each other. In one embodiment, the first outermost layer 51 and the second outermost layer 52 are formed by performing sputtering with use of the same target under the same condition. The material for forming the first outermost layer 51 and the material for forming the second outermost layer 52 preferably include an oxide containing at least one selected from tantalum, titanium, aluminum, yttrium, and lanthanum. When such material is used, joining to be described later can be satisfactorily performed.

Next, the first part 61 and the second part 62 are directly joined to each other. At the time of the direct joining, it is preferred to activate each of the first part 61 and the second part 62 by any appropriate activation treatment.

The activation treatment is typically performed by irradiating the surface with a neutralized beam. The activation treatment is preferably performed by generating the neutralized beam with an apparatus such as an apparatus as described in JP 2014-086400 A, and irradiating the surface with the beam. Specifically, a saddle-field fast atom beam (FAB) source is used as a beam source, and an inert gas, such as argon or xenon, is introduced into the chamber of the source, followed by the application of a high voltage from a DC power source thereof to an electrode thereof. Thus, a saddle-field electric field is generated between the electrode (positive electrode) and the casing (negative electrode) thereof to cause electron motion, to thereby generate the beams of an atom and an ion by the inert gas. Of the beams that have reached the grid of the apparatus, an ion beam is neutralized by the grid, and hence the beam of a neutral atom is emitted from the fast atom beam source. The voltage at the time of the activation treatment by the beam irradiation is preferably set to from 0.5 kV to 2.0 kV, and a current at the time of the activation treatment by the beam irradiation is preferably set to from 50 mA to 200 mA.

FIG. 3C is an illustration of a state in which each of a surface 61a of the first part 61 and a surface 62a of the second part 62 is subjected to activation treatment. Typically, activation of the surface 61a of the first part 61 and activation of the surface 62a of the second part 62 may be performed at the same time. The length of time of the activation treatment (e.g., the length of time of the beam irradiation described above) is preferably from 10 seconds to 30 seconds for each of the surfaces.

The direct joining is performed by, after the activation treatment, bringing the first part 61 and the second part 62 into contact with each other, and applying a pressure to the resultant. Thus, a joined body (composite substrate) 102 illustrated in FIG. 3D is obtained. The contact and the application of a pressure are preferably performed in a vacuum atmosphere. A temperature at this time is typically normal temperature. Specifically, the temperature is preferably 20° C. or more and 40° C. or less, more preferably 25° C. or more and 30° C. or less. A pressure to be applied is preferably from 100 N to 20,000 N.

The first outermost layer 51 and the second outermost layer 52 are joined to each other to form the first refractive index layer 21₁. A joining interface may be present in the central portion of the first refractive index layer 21₁ to be obtained in the thickness direction. The thicknesses of the first outermost layer 51 and the second outermost layer 52 may be appropriately set in accordance with a desired thickness of the first refractive index layer 21₁. Each of the thicknesses of the first outermost layer 51 and the second outermost layer 52 is preferably 20 nm or more and 200 nm or less, more preferably 30 nm or more and 175 nm or less. A ratio of the thickness of the second outermost layer 52 to the thickness of the first outermost layer 51 is, for example, from 0.3 to 2.4. An inert gas atom to be used for the activation treatment may be present near the joining interface. In addition, near the joining interface, an amorphous structure (e.g., an amorphous region containing the inert gas atom) may also be generated by the activation treatment.

When the joining interface is positioned inside one refractive index layer included in the multilayer film, an influence of the activation treatment on the multilayer film for which highly precise control of refractive indices may be demanded can be made extremely small. For example, an inert gas atom to be used for the activation treatment is substantially absent in the wavelength conversion layer, and mixing-in of the wavelength conversion material, a material for forming the substrate and/or the function layer, and the like into the multilayer film due to the activation treatment can accordingly be suppressed. As a result, the refractive index layer included in the multilayer film can have a desired refractive index and, for example, a desired reflection characteristic as an entire multilayer film can be satisfactorily achieved. The refractive index may be changed by generation of the amorphous structure due to the activation treatment, but mixing-in of the wavelength conversion material due to the activation treatment is considered to have a larger influence.

After the direct joining, the joined body 102 may be subjected to annealing treatment. Specifically, the joined body 102 may be heated. When the annealing treatment is performed, the inert gas atom and impurities (e.g., impurities derived from a jig and a seat portion of an activation treatment apparatus) can be volatilized through diffusion. In addition, crystallization of a portion in an amorphous state is also expected from the annealing treatment, and, for example, a further improvement of the reflection characteristic can be expected. A temperature of the annealing treatment (heating temperature) is, for example, from 300° C. to 450° C.

At the time of the joining, the surface of each of the first part 61 and the second part 62 is preferably a flat surface. Specifically, the arithmetic mean roughness Ra of the surfaces of the first part 61 and the second part 62 is preferably 5 nm or less, more preferably 2 nm or less, still more preferably 1 nm or less, particularly preferably 0.3 nm or less. A method of flattening the surface is, for example, mirror polishing through chemical-mechanical polishing (CMP) or lap polishing.

At the time of the film formation and the joining described above, the surface of each layer is preferably washed in order to, for example, remove the residue of a polishing agent. A method for the washing is, for example, wet washing, dry washing, or scrub washing. Of those, scrub washing is preferred because the surface can be simply and efficiently washed. A specific example of the scrub washing is a method including washing the surface in a scrub washing machine with a detergent (e.g., a SUNWASH series manufactured by Lion Corporation) and then with a solvent (e.g., a mixed solution of acetone and isopropyl alcohol (IPA)).

In FIG. 3, the production of a joined body of the wavelength conversion layer 10 and the first multilayer film 21 by forming the first part 61 on the substrate 30 is illustrated. In the same manner as in the example illustrated in FIG. 3, a joined body of the wavelength conversion layer 10 and the second multilayer film 22 can be obtained by forming the first part 61 on the function layer 40 and joining the resultant to the wavelength conversion layer 10. In a case of obtaining the composite substrate illustrated in FIG. 1, an order in which the substrate 30 and the function layer 40 are laminated onto the wavelength conversion layer 10 is not particularly limited. Specifically, the function layer 40 may be joined to the wavelength conversion layer 10 after the substrate 30 is joined to the wavelength conversion layer 10, or the substrate 30 may be joined to the wavelength conversion layer 10 after the function layer 40 is joined to the wavelength conversion layer 10.

### EXAMPLES

The present disclosure is specifically described below by way of Examples. However, the present disclosure is not limited by these Examples.

### Example 1

Tantalum oxide (Ta₂O₅) layers, silicon oxide (SiO₂) layers, and aluminum oxide (Al₂O₃) layers are formed on a substrate (GaAs substrate) in the order and thickness shown in Table 1. A laminated portion including twenty-eight layers from the twenty-ninth refractive index layer to the second refractive index layer and a tantalum oxide layer having a thickness of 100 nm is thus formed. A tantalum oxide layer having a thickness of 100 nm is formed on an Yb:YAG substrate, and the two substrates are joined to each other by the method illustrated in FIG. 3 to provide a composite substrate. Refractive indices of the respective layers of the composite substrate are summarized in Table 1.

As shown in Table 1, the influence (generation of an amorphous structure) of the activation treatment (beam irradiation) on the first refractive index layer (tantalum oxide layer having a thickness of 200 nm) is extremely small, and a desired refractive index is obtained.

### Comparative Example 1

Tantalum oxide (Ta₂O₅) layers, silicon oxide (SiO₂) layers, and aluminum oxide (Al₂O₃) layers are formed on a substrate (GaAs substrate) in the same manner as in Example 1 to form a total of twenty-eight layers from the twenty-ninth refractive index layer to the second refractive index layer, and a tantalum oxide layer having a thickness of 200 nm is further formed. Then, a surface of the tantalum oxide layer having a thickness of 200 nm of the GaAs substrate, and a surface of a separately prepared Yb:YAG substrate are subjected to activation treatment. The two substrates are joined to each other to provide a composite substrate. Refractive indices of the respective layers of the composite substrate are summarized in Table 1.

As shown in Table 1, on an Yb:YAG layer side of the first refractive index layer (tantalum oxide layer), a layer (thickness: 50 nm) having a refractive index lower than the refractive index (2.23) of the tantalum oxide is formed by the activation treatment (beam irradiation). It can be recognized that, in this layer (region), there are components for forming YAG.

TABLE 1

| | | | Example 1 | | Comparative Example 1 | |
|---|---|---|---|---|---|---|
| | | | Refractive | Thickness | Refractive | Thickness |
| Composite substrate | | | index | (nm) | index | (nm) |
| Wavelength | | Yb:YAG | 1.83 | — | 1.83 | — |
| conversion | | | | | | |
| layer | | | | | | |
| Refractive | 1 | Ta₂O₅ | 2.23 | 200 | 2.00 | 50 |
| index layer | | | | | 2.23 | 150 |
| | 2 | SiO₂ | 1.46 | 290 | 1.46 | 290 |
| | 3 | Ta₂O₅ | 2.23 | 240 | 2.23 | 240 |
| | 4 | SiO₂ | 1.46 | 175 | 1.46 | 175 |
| | 5 | Ta₂O₅ | 2.23 | 110 | 2.23 | 110 |
| | 6 | SiO₂ | 1.46 | 260 | 1.46 | 260 |
| | 7 | Ta₂O₅ | 2.23 | 125 | 2.23 | 125 |
| | 8 | SiO₂ | 1.46 | 194 | 1.46 | 194 |
| | 9 | Ta₂O₅ | 2.23 | 114 | 2.23 | 114 |
| | 10 | SiO₂ | 1.46 | 211 | 1.46 | 211 |
| | 11 | Ta₂O₅ | 2.23 | 96 | 2.23 | 96 |
| | 12 | SiO₂ | 1.46 | 201 | 1.46 | 201 |
| | 13 | Ta₂O₅ | 2.23 | 125 | 2.23 | 125 |
| | 14 | SiO₂ | 1.46 | 179 | 1.46 | 179 |
| | 15 | Ta₂O₅ | 2.23 | 125 | 2.23 | 125 |
| | 16 | SiO₂ | 1.46 | 196 | 1.46 | 196 |
| | 17 | Ta₂O₅ | 2.23 | 125 | 2.23 | 125 |
| | 18 | SiO₂ | 1.46 | 206 | 1.46 | 206 |
| | 19 | Ta₂O₅ | 2.23 | 106 | 2.23 | 106 |
| | 20 | SiO₂ | 1.46 | 210 | 1.46 | 210 |
| | 21 | Ta₂O₅ | 2.23 | 124 | 2.23 | 124 |
| | 22 | SiO₂ | 1.46 | 208 | 1.46 | 208 |
| | 23 | Ta₂O₅ | 2.23 | 95 | 2.23 | 95 |
| | 24 | SiO₂ | 1.46 | 216 | 1.46 | 216 |
| | 25 | Al₂O₃ | 1.63 | 105 | 1.63 | 105 |
| | 26 | SiO₂ | 1.46 | 216 | 1.46 | 216 |
| | 27 | Al₂O₃ | 1.63 | 237 | 1.63 | 237 |
| | 28 | SiO₂ | 1.46 | 90 | 1.46 | 90 |
| | 29 | Ta₂O₅ | 2.23 | 62 | 2.23 | 62 |

| | | | | | |
|---|---|---|---|---|---|
| Substrate | GaAs | 3.40 | 4,842 | 3.4 | 4,842 |

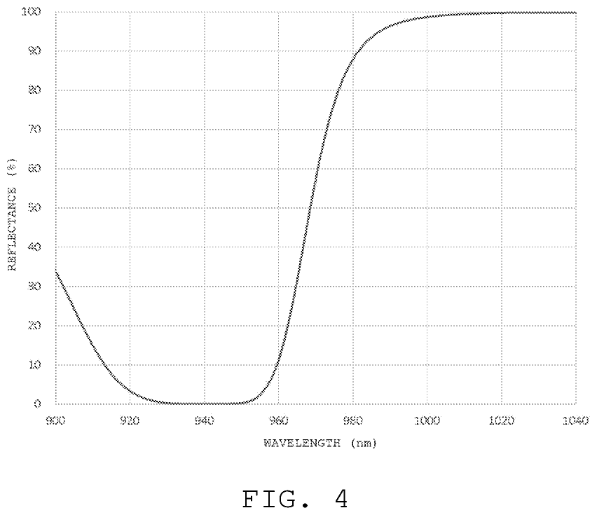

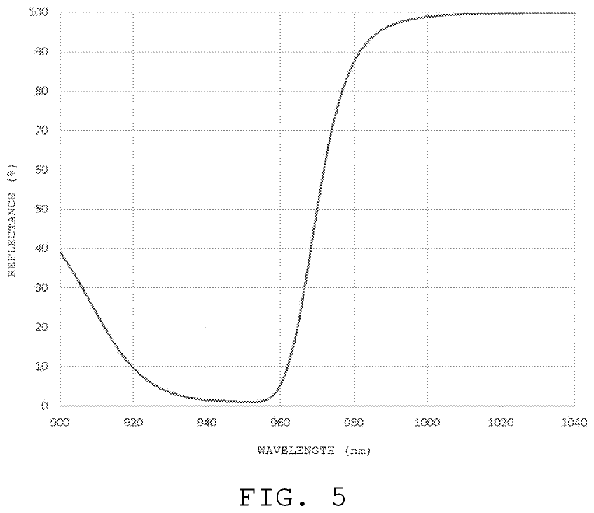

A simulation result of a reflection characteristic of a multilayer film in Example 1 is shown in FIG. 4, and a simulation result of a reflection characteristic of a multilayer film in Comparative Example 1 is shown in FIG. 5.

Yb:YAG has an effective excitation wavelength of from 935 nm to 945 nm, and is capable of conversion to light having a wavelength of 1,030 nm. The multilayer films in Example 1 and Comparative Example 1 transmit light having a wavelength that is the effective excitation wavelength of the wavelength conversion layer (Yb:YAG layer), and are capable of suppressing emission of light having a wavelength of 1,030 nm to be emitted from the wavelength conversion layer (Yb:YAG layer).

While the multilayer film in Example 1 had a reflectance of 0.1% at a wavelength of 940 nm, the multilayer film in Comparative Example 1 had a reflectance of 1.5% at a wavelength of 940 nm. It can be said from this that the multilayer film in Example 1 is more effective in terms of incidence of light having a wavelength that is the effective excitation wavelength of the wavelength conversion layer (Yb:YAG layer).

### (Composition Analysis of Example 1)

On a GaAs substrate, layers from the twenty-ninth refractive index layer to the second refractive index layer shown in Table 1 were sequentially formed in materials and thicknesses shown in Table 1. Then, lastly, a tantalum oxide layer having a thickness of 100 nm was formed to form a laminated structure. In addition, a tantalum oxide layer having a thickness of 100 nm was formed on an Yb:YAG substrate (YAG crystal).

Next, a surface (tantalum oxide layer side) of the Yb:YAG substrate on which the tantalum oxide layer had been formed and a surface (tantalum oxide layer side) of the GaAs substrate on which the laminated structure had been formed were washed. The two substrates were then loaded into a vacuum chamber, a vacuum on the order of 10-6 Pa was reached by vacuuming, and the surfaces of the two substrates were simultaneously irradiated for 20 seconds with FABs (acceleration voltage: 1 kV, Ar flow rate: 27 sccm) that use Ar gas.

Next, the GaAs substrate and the Yb:YAG substrate were directly joined to each other. Specifically, the surfaces of the two substrates that had been irradiated with FABs on top of one another were superimposed on each other, and both the surfaces were joined to each other by applying a pressure thereto at 10,000 N for 2 minutes at normal temperature to provide a joined body as illustrated in each of FIG. 2 and FIG. 3D.

The resultant joined body was then subjected to annealing treatment. Specifically, the resultant joined body was placed in a high-temperature furnace, and in this state, the temperature in the high-temperature furnace was increased from room temperature to a temperature higher than 100° C., followed by maintaining for a certain period of time. After that, the temperature was returned to room temperature to perform annealing.

In order to measure contents (abundances) of Ar in the respective layers for forming the joined body, surfaces of the respective layers were exposed by thinning the joined body by a focused ion beam (FIB) method, and energy dispersive X-ray analysis (EDX) was performed. Specifically, the analysis was performed by STEM-EDX observation using an atomic resolution analytical electron microscope (manufactured by JEOL Ltd., JEM-ARM200F Dual-X) and an energy dispersive X-ray analyzer (manufactured by JEOL Ltd., JED-2300) with an acceleration voltage of 200 kV and a beam spot size of about 0.2 nmΦ.

Measurement results are given below. An Ar content refers to the proportion of Ar atoms to all atoms present at a measurement site.
Measurement site 1 (YAG crystal corresponding to the wavelength conversion layer 10): 0 at %
Measurement site 2 (first refractive index layer 21₁, the first outermost layer 51 side): 0.7 at %
Measurement site 3 (first refractive index layer 21₁, the second outermost layer 52 side): 0.7 at %
Measurement site 4: (silicon oxide layer corresponding to the second refractive index layer 21₂): 0 at %

### Example 2

Tantalum oxide (Ta₂O₅) layers, silicon oxide (SiO₂) layers, and aluminum oxide (Al₂O₃) layers are formed on a Cr:YAG substrate in the order and thickness shown in Table 2. A laminated portion including thirty-two layers from the thirty-third refractive index layer to the second refractive index layer and a tantalum oxide layer having a thickness of 80 nm is thus formed. A tantalum oxide layer having a thickness of 80 nm is formed on an Yb:YAG substrate, and the two substrates are joined to each other by the method illustrated in FIG. 3 to provide a composite substrate. Refractive indices of the respective layers of the composite substrate are summarized in Table 2.

TABLE 2

Example 2

| | | | Refractive | Thickness |
|---|---|---|---|---|
| Composite substrate | | | index | (nm) |
| Wavelength | | Yb:YAG | 1.83 | — |
| conversion layer | | | | |
| Refractive | 1 | Ta₂O₅ | 2.23 | 160 |
| index layer | 2 | SiO₂ | 1.46 | 279 |
| | 3 | Al₂O₃ | 1.63 | 257 |
| | 4 | SiO₂ | 1.46 | 238 |
| | 5 | Ta₂O₅ | 2.23 | 259 |
| | 6 | SiO₂ | 1.46 | 260 |
| | 7 | Ta₂O₅ | 2.23 | 260 |
| | 8 | SiO₂ | 1.46 | 260 |
| | 9 | Ta₂O₅ | 2.23 | 260 |
| | 10 | SiO₂ | 1.46 | 260 |
| | 11 | Ta₂O₅ | 2.23 | 260 |
| | 12 | SiO₂ | 1.46 | 260 |
| | 13 | Ta₂O₅ | 2.23 | 260 |
| | 14 | SiO₂ | 1.46 | 260 |
| | 15 | Ta₂O₅ | 2.23 | 260 |
| | 16 | SiO₂ | 1.46 | 260 |
| | 17 | Ta₂O₅ | 2.23 | 260 |
| | 18 | SiO₂ | 1.46 | 260 |
| | 19 | Ta₂O₅ | 2.23 | 260 |
| | 20 | SiO₂ | 1.46 | 260 |
| | 21 | Ta₂O₅ | 2.23 | 260 |
| | 22 | SiO₂ | 1.46 | 260 |
| | 23 | Ta₂O₅ | 2.23 | 260 |
| | 24 | SiO₂ | 1.46 | 260 |
| | 25 | Ta₂O₅ | 2.23 | 260 |
| | 26 | SiO₂ | 1.46 | 260 |
| | 27 | Ta₂O₅ | 2.23 | 260 |
| | 28 | SiO₂ | 1.46 | 260 |
| | 29 | Al₂O₃ | 1.63 | 260 |
| | 30 | SiO₂ | 1.46 | 260 |
| | 31 | Ta₂O₅ | 2.23 | 190 |
| | 32 | Al₂O₃ | 1.63 | 260 |
| | 33 | SiO₂ | 1.46 | 75 |

| | | | |
|---|---|---|---|
| Function layer | Cr:YAG | 1.82 | 8,216 |

As shown in Table 2, the influence of the activation treatment (beam irradiation) on the first refractive index layer (tantalum oxide layer) is extremely small, and a desired refractive index is obtained.

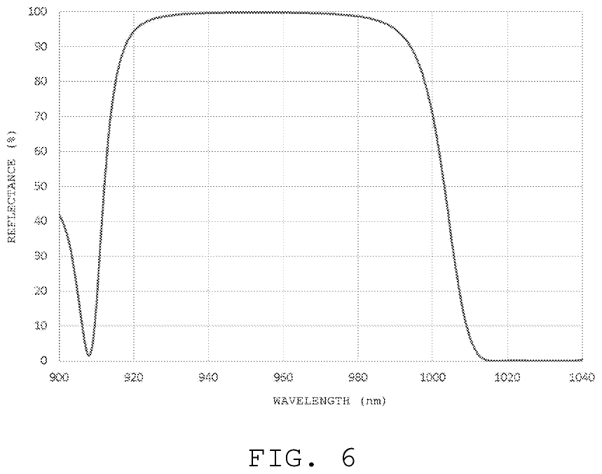

A simulation result of a reflection characteristic of a multilayer film in Example 2 is shown in FIG. 6.

The multilayer film in Example 2 transmits light having a wavelength of 1,030 nm to be emitted from the wavelength conversion layer (Yb:YAG layer), and is capable of suppressing emission of light having a wavelength that is the effective excitation wavelength of the wavelength conversion layer (Yb:YAG layer).

### Example 3

Titanium oxide (TiO₂) layers, silicon oxide (SiO₂) layers, and aluminum oxide (Al₂O₃) layers are formed on a substrate (GaAs substrate) in the order and thickness shown in Table 3. A laminated portion including twenty-eight layers from the twenty-ninth refractive index layer to the second refractive index layer and a titanium oxide layer having a thickness of 91 nm is thus formed. A titanium oxide layer having a thickness of 91 nm is formed on an Yb:YAG substrate, and the two substrates are joined to each other by the method illustrated in FIG. 3 to provide a composite substrate. Refractive indices of the respective layers of the composite substrate are summarized in Table 3.

As shown in Table 3, the influence (generation of an amorphous structure) of the activation treatment (beam irradiation) on the first refractive index layer (titanium oxide layer having a thickness of 182 nm) is extremely small, and a desired refractive index is obtained.

TABLE 3

Example 3

| | Refractive | Thickness |
|---|---|---|
| Composite substrate | index | (nm) |

| | | | |
|---|---|---|---|
| Wavelength | Yb:YAG | 1.83 | — |
| conversion layer | | | |
| 1 | TiO₂ | 2.35 | 182 |
| 2 | SiO₂ | 1.46 | 285 |
| 3 | TiO₂ | 2.35 | 236 |
| 4 | SiO₂ | 1.46 | 172 |
| 5 | TiO₂ | 2.35 | 113 |
| 6 | SiO₂ | 1.46 | 251 |
| 7 | TiO₂ | 2.35 | 123 |
| 8 | SiO₂ | 1.46 | 191 |
| 9 | TiO₂ | 2.35 | 112 |
| 10 | SiO₂ | 1.46 | 207 |
| 11 | TiO₂ | 2.35 | 95 |
| 12 | SiO₂ | 1.46 | 198 |
| 13 | TiO₂ | 2.35 | 123 |
| 14 | SiO₂ | 1.46 | 176 |
| 15 | TiO₂ | 2.35 | 123 |
| 16 | SiO₂ | 1.46 | 193 |
| 17 | TiO₂ | 2.35 | 123 |
| 18 | SiO₂ | 1.46 | 202 |
| 19 | TiO₂ | 2.35 | 105 |
| 20 | SiO₂ | 1.46 | 206 |
| 21 | TiO₂ | 2.35 | 122 |
| 22 | SiO₂ | 1.46 | 206 |
| 23 | TiO₂ | 2.35 | 98 |
| 24 | SiO₂ | 1.46 | 211 |
| 25 | Al₂O₃ | 1.63 | 103 |
| 26 | SiO₂ | 1.46 | 212 |
| 27 | Al₂O₃ | 1.63 | 233 |
| 28 | SiO₂ | 1.46 | 108 |
| 29 | TiO₂ | 2.35 | 61 |
| Substrate | GaAs | 3.40 | 4,842 |

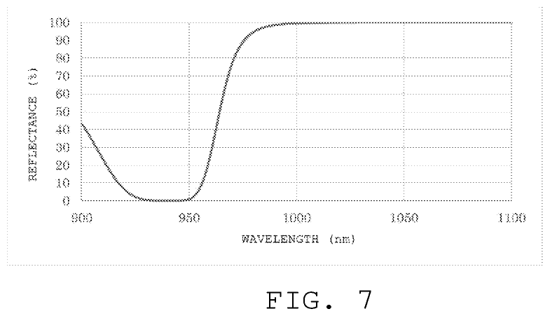

A simulation result of a reflection characteristic of a multilayer film in Example 3 is shown in FIG. 7.

Yb:YAG has an effective excitation wavelength of from 935 nm to 945 nm, and is capable of conversion to light having a wavelength of 1,030 nm. The multilayer film in Example 3 transmits light having a wavelength that is the effective excitation wavelength of the wavelength conversion layer (Yb:YAG layer), and is capable of suppressing emission of light having a wavelength of 1,030 nm to be emitted from the wavelength conversion layer (Yb:YAG layer).

The multilayer film in Example 3 had a reflectance of 0.1% at a wavelength of 940 nm.

### (Composition Analysis of Example 3)

Composition analysis was performed by STEM-EDX observation in the same manner as in Example 1 at the sites described below.
Measurement site 2 (first refractive index layer 21₁, the first outermost layer 51 side)
Measurement site 3 (first refractive index layer 21₁, the second outermost layer 52 side)

As a result, no constituent elements of Yb:YAG (Y, Al, and Yb) or no constituent element of the second refractive index layer (Si) was observed at the measurement site 2 and the measurement site 3.

### Example 4

Zirconium oxide (ZrO₂) layers, silicon oxide (SiO₂) layers, and aluminum oxide (Al₂O₃) layers are formed on a substrate (GaAs substrate) in the order and thickness shown in Table 4. A laminated portion including twenty-eight layers from the twenty-ninth refractive index layer to the second refractive index layer and a zirconium oxide layer having a thickness of 100 nm is thus formed. A zirconium oxide layer having a thickness of 100 nm is formed on an Yb:YAG substrate, and the two substrates are joined to each other by the method illustrated in FIG. 3 to provide a composite substrate. Refractive indices of the respective layers of the composite substrate are summarized in Table 4.

As shown in Table 4, the influence (generation of an amorphous structure) of the activation treatment (beam irradiation) on the first refractive index layer (zirconium oxide layer having a thickness of 200 nm) is extremely small, and a desired refractive index is obtained.

TABLE 4

Example 4

| | Refractive | Thickness |
|---|---|---|
| Composite substrate | index | (nm) |

| | | | |
|---|---|---|---|
| Wavelength | Yb:YAG | 1.83 | — |
| conversion layer | | | |
| 1 | ZrO₂ | 2.07 | 200 |
| 2 | SiO₂ | 1.46 | 280 |
| 3 | ZrO₂ | 2.07 | 240 |
| 4 | SiO₂ | 1.46 | 179 |
| 5 | ZrO₂ | 2.07 | 110 |
| 6 | SiO₂ | 1.46 | 266 |
| 7 | ZrO₂ | 2.07 | 128 |
| 8 | SiO₂ | 1.46 | 198 |
| 9 | ZrO₂ | 2.07 | 116 |
| 10 | SiO₂ | 1.46 | 215 |
| 11 | ZrO₂ | 2.07 | 98 |
| 12 | SiO₂ | 1.46 | 205 |
| 13 | ZrO₂ | 2.07 | 128 |
| 14 | SiO₂ | 1.46 | 187 |
| 15 | ZrO₂ | 2.07 | 128 |
| 16 | SiO₂ | 1.46 | 200 |
| 17 | ZrO₂ | 2.07 | 128 |
| 18 | SiO₂ | 1.46 | 210 |
| 19 | ZrO₂ | 2.07 | 109 |
| 20 | SiO₂ | 1.46 | 215 |
| 21 | ZrO₂ | 2.07 | 126 |
| 22 | SiO₂ | 1.46 | 212 |
| 23 | ZrO₂ | 2.07 | 97 |
| 24 | SiO₂ | 1.46 | 221 |
| 25 | Al₂O₃ | 1.63 | 107 |
| 26 | SiO₂ | 1.46 | 221 |
| 27 | Al₂O₃ | 1.63 | 235 |
| 28 | SiO₂ | 1.46 | 71 |
| 29 | ZrO₂ | 2.07 | 75 |
| Substrate | GaAs | 3.40 | 4,842 |

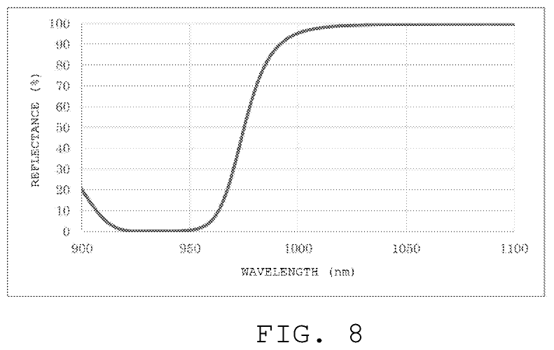

A simulation result of a reflection characteristic of a multilayer film in Example 4 is shown in FIG. 8.

Yb:YAG has an effective excitation wavelength of from 935 nm to 945 nm, and is capable of conversion to light having a wavelength of 1,030 nm. The multilayer film in Example 4 transmits light having a wavelength that is the effective excitation wavelength of the wavelength conversion layer (Yb:YAG layer), and is capable of suppressing emission of light having a wavelength of 1,030 nm to be emitted from the wavelength conversion layer (Yb:YAG layer).

The multilayer film in Example 4 had a reflectance of 0.1% at a wavelength of 940 nm.

### (Composition Analysis of Example 4)

Composition analysis was performed by STEM-EDX observation in the same manner as in Example 1 at the sites described below.
Measurement site 2 (first refractive index layer 21₁, the first outermost layer 51 side)
Measurement site 3 (first refractive index layer 21₁, the second outermost layer 52 side)

As a result, no constituent elements of Yb:YAG (Y, Al, and Yb) or no constituent element of the second refractive index layer (Si) was observed at the measurement site 2 and the measurement site 3.

The composite substrate according to the embodiment of the present disclosure can be suitably used in laser devices for sensing, precision processing, medicine, and the like.

What is claimed is:

1. A composite substrate, comprising:
a wavelength conversion layer configured to convert incident light into light having a different wavelength; and
a multilayer film arranged adjacent to the wavelength conversion layer,
wherein the multilayer film is a laminate of a plurality of refractive index layers, and
wherein, in one of the plurality of refractive index layers included in the multilayer film, an amorphous region in which an inert gas atom is present is formed in a central portion in a thickness direction.

2. The composite substrate according to claim 1, wherein an abundance of the inert gas atom in the amorphous region is 0.5 at % or more and 10 at % or less.

3. The composite substrate according to claim 1, wherein the wavelength conversion layer is selected from a doped yttrium aluminum garnet crystal, a doped yttrium vanadate crystal, and a doped yttrium lithium fluoride crystal.

4. The composite substrate according to claim 1, wherein the one of the plurality of refractive index layers in which the amorphous region in which the inert gas atom is present is formed includes an oxide containing at least one selected from tantalum, titanium, aluminum, yttrium, zirconium, hafnium, lanthanum, cerium, tungsten, zinc, niobium, and magnesium.

5. The composite substrate according to claim 1, wherein two neighboring layers included in the multilayer film have refractive indices different from each other.

6. The composite substrate according to claim 1,
wherein the plurality of refractive index layers included in the multilayer film each have a refractive index of from 1.3 to 2.4, and
wherein the multilayer film includes one or more refractive index layers each having a refractive index of 2.1 or more.

7. The composite substrate according to claim 1, wherein, in the multilayer film, a difference between a highest refractive index and a lowest refractive index among refractive indices of the plurality of refractive index layers is 0.5 or more.

8. The composite substrate according to claim 1, wherein the plurality of refractive index layers included in the multilayer film each have a thickness of 50 nm or more and 300 nm or less.

9. The composite substrate according to claim 1, wherein the composite substrate comprises the wavelength conversion layer, the multilayer film, and a surface emitting laser substrate in the stated order.

10. The composite substrate according to claim 1, wherein the composite substrate comprises the wavelength conversion layer, the multilayer film, and a saturable absorber layer in the stated order.

11. A composite substrate, comprising in the following order:
a surface emitting laser substrate;
a wavelength conversion layer configured to convert incident light into light having a different wavelength; and
a saturable absorber layer,
wherein the composite substrate further comprises a multilayer film arranged adjacent to the wavelength conversion layer, in at least one of a space between the surface emitting laser substrate and the wavelength conversion layer or a space between the saturable absorber layer and the wavelength conversion layer,
wherein the multilayer film is a laminate of a plurality of refractive index layers, and
wherein, in one of the plurality of refractive index layers included in the multilayer film, an amorphous region in which an inert gas atom is present is formed in a central portion in a thickness direction.

12. A laser structure, comprising the composite substrate of claim 1.

13. A method of producing the composite substrate of claim 1, the method comprising:
preparing a first part for forming the laminate of the plurality of refractive index layers;
laminating a second part for forming the laminate of the plurality of refractive index layers onto the wavelength conversion layer;
subjecting each of a surface of the first part and a surface of the second part to activation treatment; and
joining the first part and the second part to each other after the activation treatment,
wherein a material for forming an outermost layer of the first part and a material for forming an outermost layer of the second part are substantially the same as each other.

14. The method of producing the composite substrate according to claim 13, wherein a length of time of the activation treatment is from 10 seconds to 30 seconds for each of the surface of the first part and the surface of the second part.
